(19) United States
(12) Patent Application Publication
(10) Pub. No.: US 2004/0002189 A1
(43) Pub. Date: Jan. 1, 2004

(54) Method of forming capacitor in semiconductor device by using a polysilicon pattern in a trapezoid shape

(76) Inventor: Byung-Jun Park, Ichon-shi (KR)

Correspondence Address: BIRCH STEWART KOLASCH & BIRCH, PO BOX 747, FALLS CHURCH, VA, 22040-0747, US

(21) Appl. No.: 10/314,296

(22) Filed: Dec. 9, 2002

(30) Foreign Application Priority Data
Jun. 29, 2002 (KR) 2002-0037261

(51) Int. Cl. H01L 21/8242; H01L 21/20

(52) U.S. Cl. 438/253; 438/396

(57) ABSTRACT

The present invention relates to a method for forming a capacitor improved on reliability of a process in a highly integrated semiconductor device. To achieve this effect, the present invention includes: forming an inter-layer insulating layer on a substrate; forming a capacitor insulating layer as high as to form a capacitor on the inter-layer insulating layer; forming a polysilicon pattern for a hard mask in a trapezoid shape on the capacitor insulating layer; removing the capacitor insulating layer located in an area providing a capacitor by using the polysilicon pattern for the hard mask as an etch barrier so as to form a capacitor hole; forming a lower electrode within the capacitor hole; and forming a dielectric thin film and an upper electrode on the lower electrode.

### FIELD OF THE INVENTION

The present invention relates to a method for forming an integration circuit in a semiconductor device; and, more particularly, to a method for forming a capacitor in a semiconductor device.

### DESCRIPTION OF RELATED ARTS

As a degree of integration of a semiconductor device, particularly, a dynamic random access memory (DRAM) device, has been advanced, an area of a memory cell, which is a basic unit for storing information, has been sharply decreases.

The decrease of the memory cell area accompanies a further decrease of a cell area for a capacitor. As a result of the decrease in the cell area, sensing margins and sensing speeds are also reduced. Furthermore, there is a problem of reducing tolerance to a soft error due to α- particles. Therefore, it is necessary to develop a method for obtaining a sufficient capacitance within the limited cell area.

The capacitance of the capacitor is defined as:

C=ε·As/d

Herein, ε, As and d represent a dielectric constant, an effective surface area of an electrode and a distance between electrodes, respectively.

Accordingly, the capacitance of the capacitor can be increased by increasing a surface area of an electrode, decreasing a thickness of a dielectric thin film or increasing a dielectric constant.

Among these factors, it is firstly considered to increase the surface area of the electrode. Such three dimensional structures of the capacitor as like concave structure, cylinder structure, multi-layered fin structure and so forth are suggested to increase the effective surface area of the electrode within the limited layout areas. However, this approach has a limitation in increasing the effective surface area of the electrode as a semiconductor device becomes extremely highly integrated.

Also, another approach of decreasing the thickness of the dielectric thin film for minimizing the distance (d) between the electrodes has also a limitation in increasing leakage currents as the thickness of the dielectric thin film decreases.

Hence, it is currently a main focus to obtain the capacitance by increasing the dielectric constant. Typically, it has been mainly used a capacitor with so-called nitride-oxide (NO) structure using a silicon oxide layer or a silicon nitride layer as a dielectric thin film. However, such materials having a high dielectric constant, e.g., Ta₂O₅ and (Ba,Sr)TiO₃ (BST) or ferroelectric materials, e.g., (Pb,Zr)TiO₃ (PZT), (Pb,La)(Zr,Ti)O₃ (PLZT), SrBi₂Ta₂O₉ (SBT), Bi₄₋ₓLaₓTi₃O₁₂ (BLT) are employed as the dielectric thin film in today.

When forming a high dielectric capacitor using high dielectric materials or a ferroelectric capacitor using ferroelectric materials as the dielectric thin film, it is also necessary to control those materials periphery to the dielectric body and fabrication processes so as to realize the unique dielectric characteristic of the high dielectric material or the ferroelectric material.

Generally, noble metals or mixtures of the noble metals, e.g., Pt, Ir, Ru, RuO₂, IrO₂ and the like are used for an upper and a lower electrode of the high dielectric or ferroelectric capacitor.

A capacitor with the concave structure is most commonly used to maintain a consistent capacitance within the limited area. However, there exists a difficulty in stably forming the lower and the upper electrodes and the dielectric thin film on a concave hole since a height of the concave hole is increasingly augmented while a width of the concave hole becomes narrower.

FIGS. 1A to 1D are cross-sectional views for illustrating a method for forming a capacitor in a semiconductor device in accordance with a prior art.

With reference to FIG. 1A, an active area 11 is formed on a substrate 10, and an inter-layer insulating layer 12 is formed on the substrate 10. Thereafter, a contact hole connected to the active area 11 by passing through the inter-layer insulating layer 12 is formed. The contact hole is then filled with conductive materials so to form a contact plug 13, and a capacitor insulating layer 14 is formed to a size of forming a capacitor thereon.

Next, a polysilicon layer 15 for a hard mask is formed, and a photosensitive pattern 16 for a capacitor hole providing a concave type capacitor is subsequently formed on the polysilicon layer 15.

Referring to FIG. 1B, the polysilicon layer 15 is selectively etched and patterned with use of the photosensitive pattern 16.

Referring to FIG. 1C, the capacitor insulating layer 14 is removed by using the patterned polysilicon layer 15 as an etch barrier, and a capacitor hole 16 is formed.

In an ultra-micro process technology for a line width below 0.12 μm, a height of the capacitor hole should be higher than about 20000 Å to obtain a required capacitance when tacking account of a dielectric constant of Ta₂O₅ used as a dielectric thin film. It is, however, impossible to form such contact hole in case of using a typical photosensitive pattern as an etch barrier. Instead, a polysilicon layer is formed for a hard mask and used as the etch barrier for forming the capacitor hole.

As the capacitor hole providing a capacitor has been progressively formed in a narrower and longer shape, profiles of the capacitor cannot be formed perpendicularly, but indeed, being deformed. Among different types of the deformation, a lower portion of the capacitor is thinner than an upper portion. This case of the deformation is denoted as ‘A’ in FIG. 1C.

The reason for this type of the deformation is because the upper portion of the capacitor hole 16 is not proceeded with an etching at its lateral sides, whereas lateral sides of the lower portion is proceeded with the etching due to scattering ions generated when etching the capacitor insulating layer 14. As a result, these two portions of the capacitor hole 16 have different thicknesses, and this difference results in void phenomenon during subsequent processes for forming an upper and a lower electrodes and a dielectric thin film within the capacitor hole 16. This case is denoted as ‘B’ in FIG. 1D.

Due to the void phenomenon, it is impossible to form stably the capacitor, and thus, reliability of operations of a semiconductor device is reduced.

### SUMMARY OF THE INVENTION

It is, therefore, an object of the present invention to provide a method for forming a capacitor improved on reliability of processes in a highly integrated semiconductor device.

In accordance with an aspect of the present invention, there is provided a method for forming an inter-layer insulating layer on a substrate; forming a capacitor insulating layer as high as to form a capacitor on the inter-layer insulating layer; forming a polysilicon pattern for a hard mask in a trapezoid shape on the capacitor insulating layer; removing the capacitor insulating layer located in an area providing a capacitor by using the polysilicon pattern for the hard mask as an etch barrier so as to form a capacitor hole; forming a lower electrode within the capacitor hole; and forming a dielectric thin film and an upper electrode on the lower electrode.

### BRIEF DESCRIPTION OF THE DRAWING(S)

The above and other objects and features of the present invention will become apparent from the following description of the preferred embodiments given in conjunction with the accompanying drawings, in which:

FIGS. 1A to 1D are cross-sectional views illustrating a method for forming a capacitor in a semiconductor device in accordance with a prior art; and

FIGS. 2A to 2D are cross-sectional views illustrating a method for forming a capacitor in a semiconductor device in accordance with a preferred embodiment of the present invention.

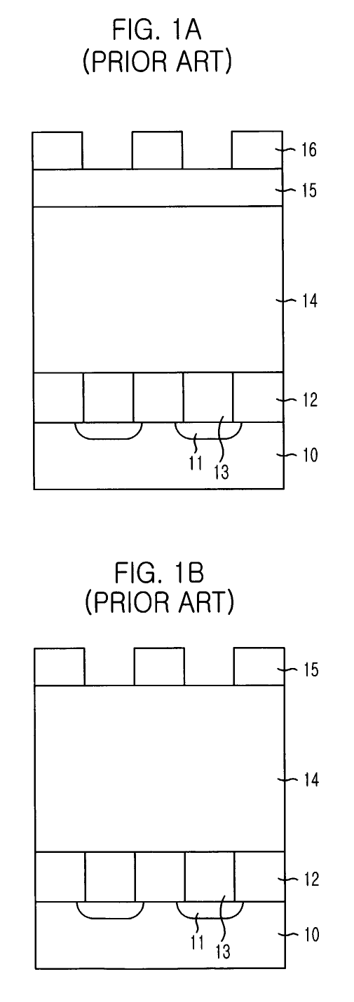

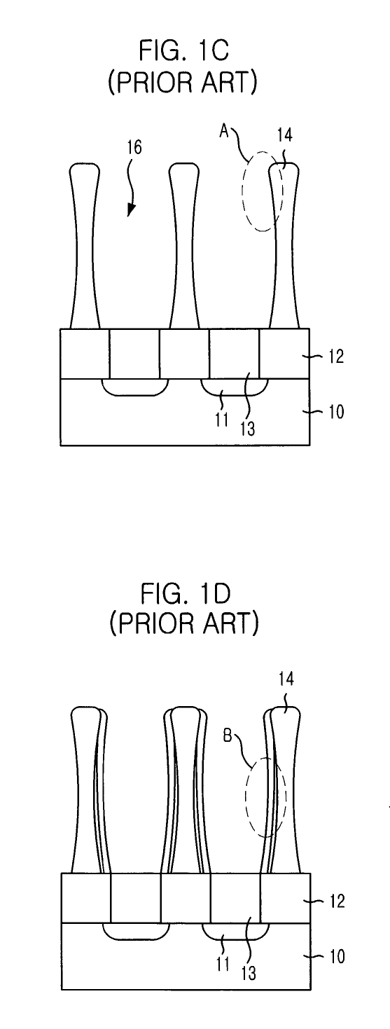

### DETAILED DESCRIPTION OF THE INVENTION

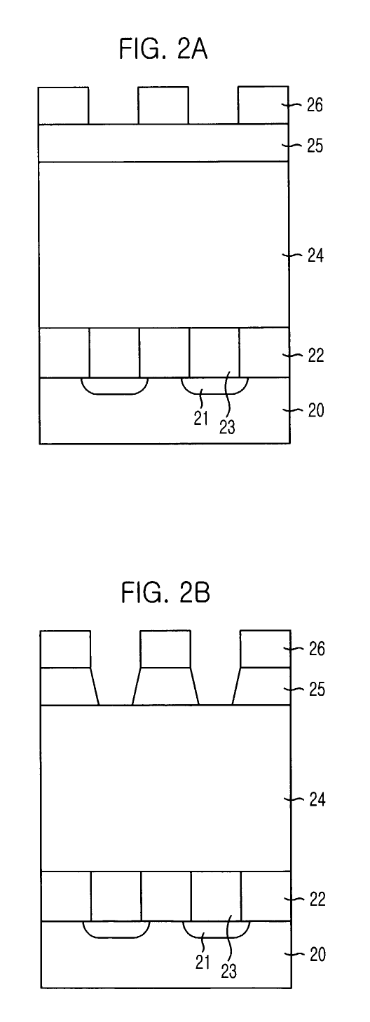

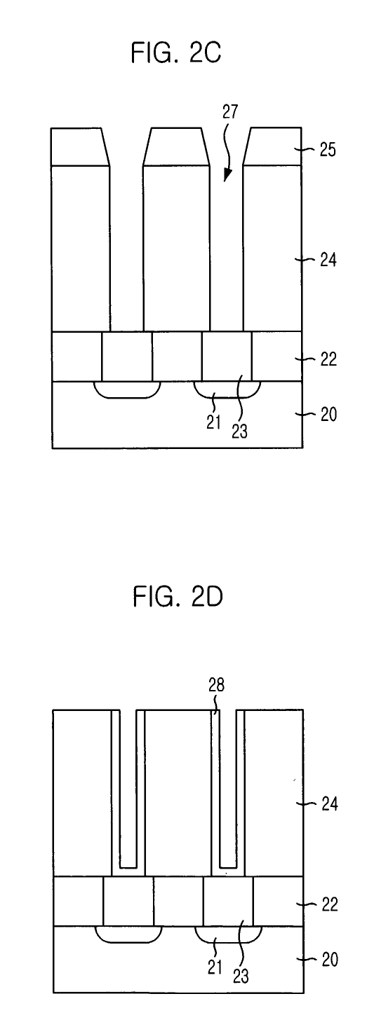

FIGS. 2A to 2D are cross-sectional views illustrating a method for forming a capacitor in a semiconductor device in accordance with a preferred embodiment of the present invention.

Referring to FIG. 2A, an inter-layer insulating layer 22 is formed on a substrate 20 providing an active area 21. A contact hole connected to the active area 21 by passing through the inter-layer insulating layer 22 is formed thereafter. The contact hole is filled with conductive materials so as to form a contact plug 23, and then, a capacitor insulating layer 24 is formed as high as to form a capacitor on top of the contact plug 23. Herein, the capacitor insulating layer 24 can use an oxide layer such as undoped-silicate glass (USG), phospho-silicate glass (PSG), boro-phospho-silicate glass (BPSG) and so on.

Next, a polysilicon layer 25 for a hard mask is formed, and a photosensitive pattern 26 is formed thereon so that a capacitor hole for forming a concave type capacitor is formed.

Referring to FIG. 2B, the polysilicon layer 25 is etched to have a slope by using the photosensitive pattern 26 as an etch barrier. At this time, high bias power is used to make a slope of the polysilicon layer 25, and one of N₂, BCl₃ or HBr gas is used as an etch gas for passivation at lateral sides of the polysilicon layer 25. Also, the etching process is proceeded with a low pressure ranging from about 1 mTorr to about 10 mTorr in an area, wherein a temperature of an electrode in an etching equipment is below about 20° C. Herein, a layer for a hard mask can be a TiN layer, a Ti layer or an W layer.

With reference to FIG. 2C, the photosensitive pattern 26 is removed, and the capacitor insulating layer 24 is etched by using the polysilicon layer 25 as an etch barrier so as to form a capacitor hole 27. At this time, the polysilicon layer 25 is patterned as sloped. Herein, if the polysilicon layer 25 is preceded with the etching process in a state of forming sloped profiles instead of perpendicular profiles, there occur losses of the polysilicon layer 25 at a bottom portion, further resulting in over-etching at an upper portion of the capacitor insulating layer 24. By following this operational scheme of the etching process, it is possible to form a capacitor hole 27 having perpendicular profiles with identical thicknesses.

Referring to FIG. 2D, a lower electrode 28 is formed within the capacitor hole 27. Then, a dielectric thin film and an upper electrode are sequentially formed thereon, completing the capacitor formation process.

As shown in the preferred embodiment, it is clearly illustrated that the upper and the lower parts of the capacitor hole have the identical thicknesses when using the sloped polysilicon layer for forming the capacitor hole.

Also, it is possible to form stably a capacitor hole with a consistent thickness, i.e., width. Therefore, it is further possible to form the upper and the lower electrodes and the dielectric thin film without any void phenomenon within the capacitor hole, thereby increasing reliability of the process in an extensively integrated semiconductor device.

While the present invention has been described with respect to certain preferred embodiments, it will be apparent to those skilled in the art that various changes and modifications may be made without departing from the scope of the invention as defined in the following claims.

What is claimed is:

1. A method for forming a capacitor in a semiconductor device, comprising the steps of:
forming an inter-layer insulating layer on a substrate;
forming a capacitor insulating layer as high as to form a capacitor on the inter-layer insulating layer;
forming a polysilicon pattern for a hard mask in a trapezoid shape on the capacitor insulating layer;
removing the capacitor insulating layer located in an area providing a capacitor by using the polysilicon pattern for the hard mask as an etch barrier so as to form a capacitor hole;
forming a lower electrode within the capacitor hole; and
forming a dielectric thin film and an upper electrode on the lower electrode.

2. The method as recited in claim 1, wherein the step of forming the polysilicon pattern for the hard mask further includes the steps of:
forming a polysilicon layer for the hard mask on the capacitor insulating layer;
forming a photosensitive pattern for forming the capacitor hole on the polysilicon layer; and
removing the polysilicon layer selectively with use of the photosensitive pattern so as to form the polysilicon pattern for the hard mask.

3. The method as recited in claim 1, wherein the step of forming the polysilicon pattern for the hard mask in the trapezoid shape employs one etch gas selected from a group consisting of N₂, BCl₃ and HBr.
